(19) United States
(12) Patent Application Publication
(10) Pub. No.: US 2008/0308901 A1
(43) Pub. Date: Dec. 18, 2008

(54) Integrated circuit having a thin passivation layer that facilitates laser programming, and applications thereof

(75) Inventors: Tzu-Hsin Huang, San Jose, CA (US); Ming Chung Chen, Newport Coast, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/808,699

(22) Filed: Jun. 12, 2007

(51) Int. Cl. H01L 29/00; H01L 21/44

(52) U.S. Cl. 257/529; 438/601; 257/E29.001; 257/E21.476

(57) ABSTRACT

An integrated circuit having a thin passivation layer that facilitates laser programming, and applications thereof. In an embodiment, the integrated circuit includes a metal layer that has at least one fuse. A passivation layer is deposited over the metal layer. The passivation layer has a thickness that is less than 4,500 angstroms in order to enable laser programming of the at least one fuse without having to etch the passivation layer in the area of the at least one fuse prior to laser programming. In embodiments, the passivation layer has a thickness that is in a range of about 2,000 angstroms to about 4,000 angstroms, and the metal layer includes copper metal conductors that are protected by a barrier metal such as, for example, titanium nitride (TiN) or silicon nitride (SiN).

### FIELD OF THE INVENTION

The present invention generally relates to integrated circuits. More particularly, it relates to integrated circuits having a thin passivation layer that facilitates laser programming, and applications thereof.

### BACKGROUND OF THE INVENTION

Many integrated circuits today are manufactured that include tens of thousands, hundreds of thousands, or even more devices. These devices are formed, for example, on a single substrate. In order to connect these devices together, multiple layers of conductors are required.

FIG. 1 illustrates a conventional integrated circuit 100. As shown in FIG. 1, integrated circuit 100 is manufactured using a substrate 102, a plurality of insulation layers 104a-n, and a plurality of metal layers 106a-n. Metal layers 106a-n include conductors that connect together the devices of integrated circuit 100.

Each metal layer 106 is separated by an inter-level dielectric or insulation layer 104. The passivation layer or top insulation layer 104n of integrated circuit 100 has a thickness of 8,000 angstroms or more. The purpose of the passivation layer is to protect, for example, the conductors and substrate of integrated circuit 100 from contaminants such as water and/or sodium. Each of the other insulation layers 104 of integrated circuit 100 also have a thickness of about 8,000 angstroms.

In some integrated circuits, the top metal layer includes programmable fuses. These fuses are programmed by blowing them with a laser, thereby enabling or disabling various logic circuits. An example of this is a processor chip where the chip contains five banks of cache memory but only requires four banks for full operation. During testing, each cache bank is exercised. If a defect is found in one bank, that bank can be disabled by blowing its programming fuse. This built-in redundancy allows higher chip yields than would be possible if all cache banks had to be perfect in every chip. If no bank is found to be defective during testing, a fuse can be blown arbitrarily thereby leaving just four banks. This process is commonly referred to by persons skilled in the relevant art(s) as laser programming.

A conventional method for manufacturing and laser programming an integrated circuit is illustrated by FIGS. 2A-D.

FIG. 2A is a diagram that illustrates the formation of a thick passivation layer 104n over a metal layer 106n that includes a fuse 202. The passivation layer 104n is typically about 8,000 angstroms thick or more. This thick passivation layer 104n is considered to be necessary in accordance with conventional wisdom in order to prevent water and/or other contaminants such as sodium from entering the active region (e.g., silicon surface) of the integrated circuit or reacting with the metal conductors of the integrated circuit.

FIG. 2B is a diagram that illustrates the after-fuse photolithography steps that are required before laser programming of fuse 202 is possible. These steps include, for example, applying a layer of photoresist 204 to the wafer, soft baking the wafer during which solvents are removed from photoresist 204; aligning a mask with the wafer, imaging a pattern onto photoresist 204; developing photoresist 204; and hard-baking the wafer in order to harden photoresist 204 and improve adhesion of photoresist 204 to the wafer.

FIG. 2C is a diagram illustrating fuse etching. Fuse etching involves etching away a significant portion of the passivation above fuse 202 to create an open window 206 for laser pass-through. A laser having optimal energy cannot pass through a thick layer of passivation. Thus, it is necessary to etch out window 206 so that the laser can impart sufficient energy to fuse 202 to blow it without damaging substrate structures.

FIG. 2D is a diagram illustrating the use of laser light 208 to blow fuse 202.

While the steps illustrated in FIGS. 2A-D work for their intended purpose, they unnecessarily add to the cost of manufacturing and laser programming an integrated circuit. Furthermore, the thick passivation layer reduces the ability of an integrated circuit to dissipate heat, and it adds to the thermal expansion and contraction stresses of an integrated circuit.

What are needed are integrated circuits, and methods and techniques for manufacturing integrated circuits, that overcome the deficiencies noted above.

### BRIEF SUMMARY OF THE INVENTION

The present invention provides integrated circuits having a thin passivation layer that facilitates laser programming, and applications thereof. In an embodiment, an integrated circuit according to the present invention includes a metal layer that has at least one fuse. A passivation layer is deposited over the metal layer. The passivation layer has a thickness that is less than 4,500 angstroms in order to enable laser programming of the at least one fuse without having to etch the passivation layer in the area of the at least one fuse prior to laser programming. In embodiments, the passivation layer has a thickness that is in a range of about 2,000 angstroms to about 4,000 angstroms in order to enable laser programming.

In embodiments of the present invention, the metal layer includes copper metal conductors. The conductors are protected by a barrier metal such as, for example, titanium nitride (TiN) or silicon nitride (SiN).

In a method embodiment of the present invention, an integrated circuit is manufactured by (1) forming at least one fuse in a metal layer of an integrated circuit; (2) depositing a passivation layer over the metal layer that is less than 4500 angstroms thick; and (3) laser programming the at least one fuse. It is a feature of this method embodiment that no after-fuse photolithography and fuse etching are required.

Further embodiments, features, and advantages of the present invention, as well as the structure and operation of the various embodiments of the present invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 is a diagram illustrating a conventional integrated circuit.

FIGS. 2A-D are diagrams illustrating conventional methods for manufacturing and laser programming an integrated circuit.

FIG. 3 is a diagram illustrating an integrated circuit according to an embodiment of the present invention.

FIGS. 4A-B are diagrams illustrating example fuses that can be programmed according to an embodiment of the present invention.

FIGS. 5A-B are diagrams illustrating methods for manufacturing and laser programming an integrated circuit according to an embodiment of the present invention.

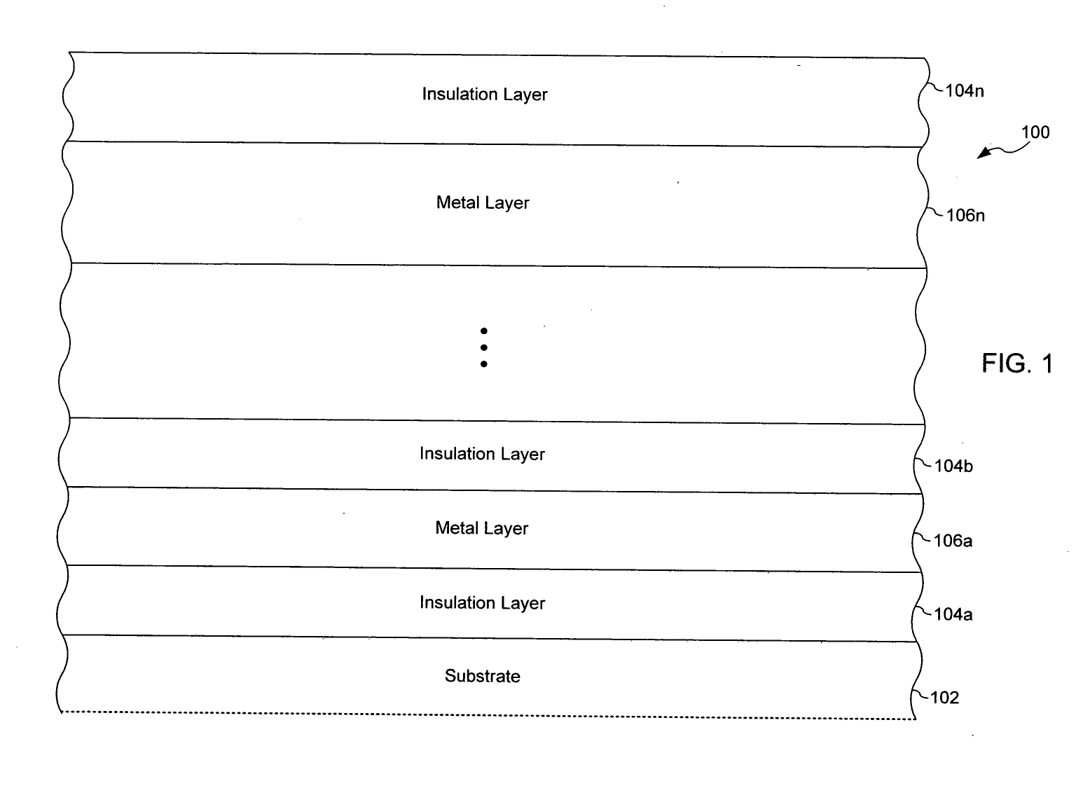

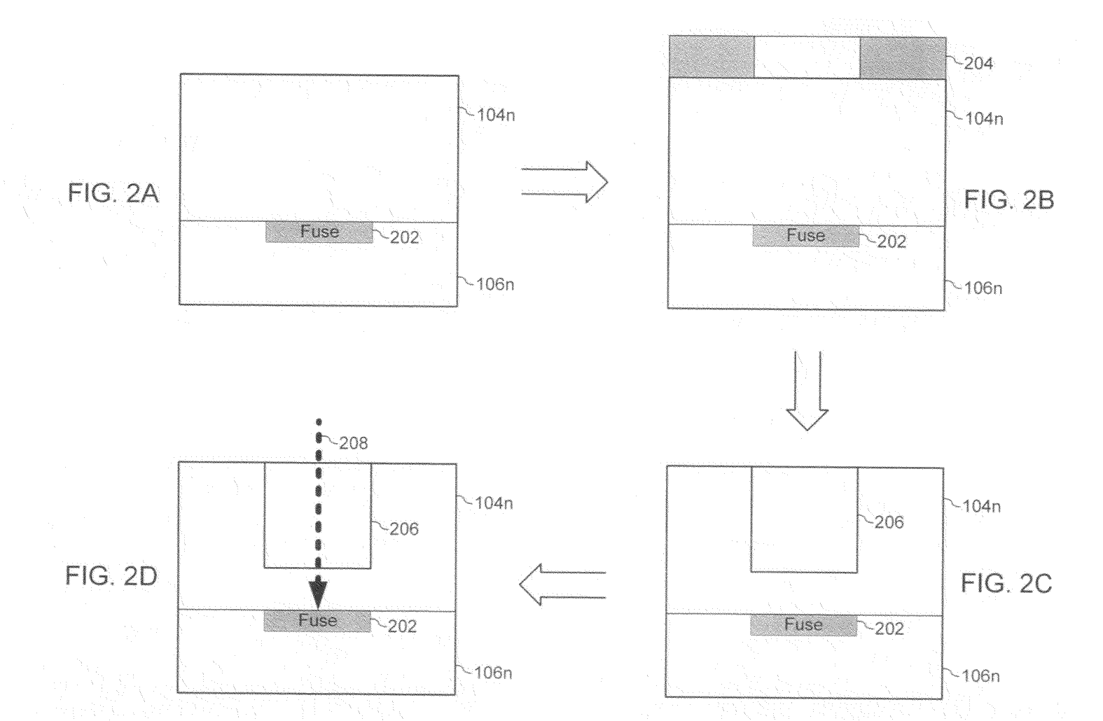

The present invention is described with reference to the accompanying drawings. The drawing in which an element first appears is typically indicated by the leftmost digit or digits in the corresponding reference number.

### DETAILED DESCRIPTION OF THE INVENTION

The present invention provides integrated circuits having a thin passivation layer that facilitates laser programming, and applications thereof. In the detailed description of the invention herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

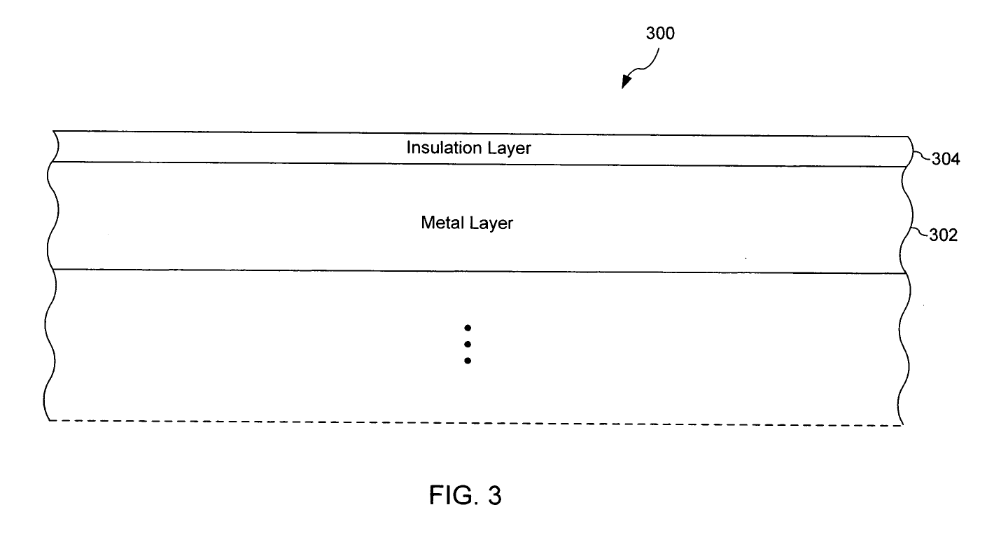

FIG. 3 is a diagram illustrating an integrated circuit 300 according to an embodiment of the present invention. As shown in FIG. 3, integrated circuit 300 includes a metal layer 302 and a passivation or insulation layer 304. In an embodiment, metal layer 302 is between about 9,000 angstroms thick and about 14,500 angstroms thick. Insulation layer 304 is less than 4,500 angstroms thick, and in embodiments it is about 2,000 angstroms thick to about 4,000 angstroms thick. The thickness of the passivation can be varied, for example, depending on the passivation material used and the laser programming parameters to be used.

In an embodiment, integrated circuit 300 is formed, for example, using a 0.13 micron process and has up to six metal layers. Each metal layer is separated by an inter-layer dielectric or insulation layer. The metal layers include copper metal conductors that are protected by a barrier metal. Thicker metal conductors are used for power circuits than are used for signal circuits in order to lower the resistance of the power circuits. In embodiments, the copper metal conductors are protected by titanium nitride or silicon nitride. Because of the number of metal layers and the number of insulation layers between the metal layers, a thick passivation layer over the top metal layer (e.g., metal layer 302) is not needed to protect the substrate. Furthermore, a thick passivation layer is not needed because the copper metal conductors are protected by a barrier metal.

In embodiments of the present invention, metal layer 302 includes one or more fuses that can be programmed (e.g., blown or cut) using laser programming. Laser fuse programming is widely used, for example, to repair integrated circuits having memory. In general, memories such as DRAMs are quite susceptible to process defects. Thus, redundant elements are formed on the substrate and switched in or out, for example, to replace defective elements by means of laser blown fuses, thereby increasing chip yield. Circuit elements other than memory can also be repaired using this technique.

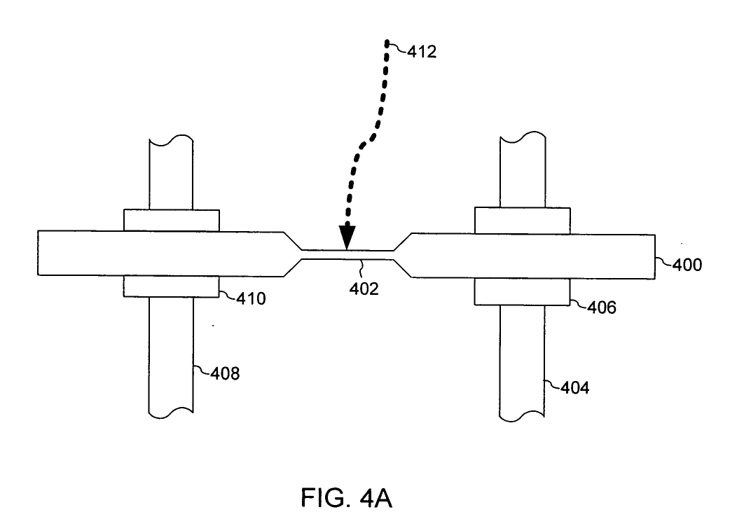

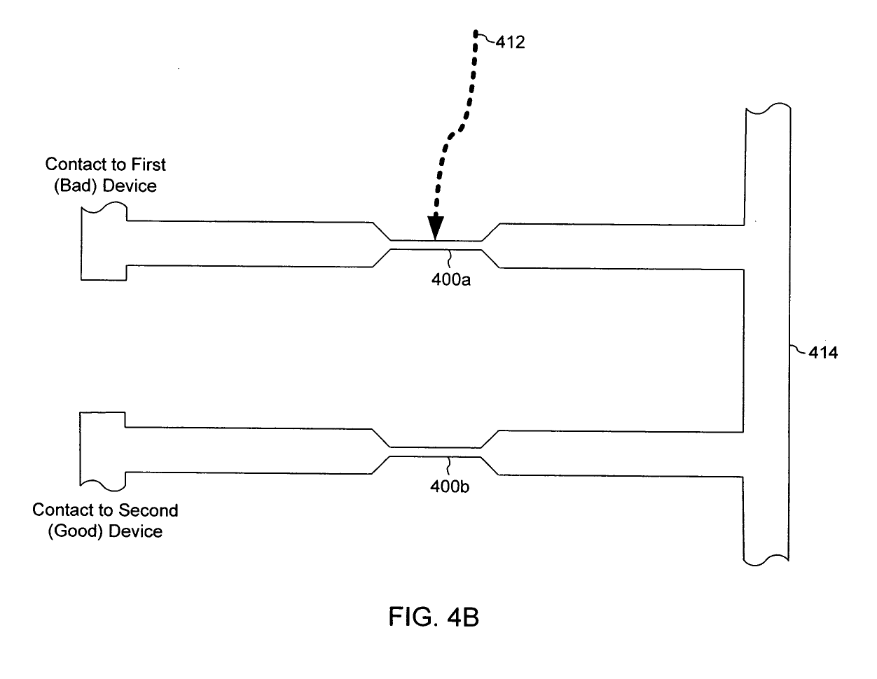

FIG. 4A illustrates an example fuse 400 that can be included in metal layer 302 and programmed using a laser according to an embodiment of the present invention. As shown in FIG. 4A, fuse 400 includes a restricted section 402 that is blown or cut whenever sufficient energy is imparted to it using laser light 412. Other fuses can also be used in accordance with the present invention.

In an embodiment, as shown in FIG. 4A, fuse 400 connects two conductors 404 and 408. Fuse 400 is connected to conductor 404 by a metal plug or contact 406. Fuse 400 is connected to conductor 408 by a metal plug or contact 410. So long as restricted section 402 of fuse 400 is intact, fuse 400 connects conductor 404 to conductor 408. However, if desired, fuse 400 can be blown using laser programming, thereby disconnecting conductor 404 from conductor 408.

FIG. 4B is a diagram that further illustrates laser fuse programming. As illustrated by FIG. 4B, two fuses 400a and 400b can be programmed according to an embodiment of the present invention to switch out a bad device. As shown in FIG. 4B, a fuse 400a connects a bus 414 to a first device, for example, that was determined to be bad during testing. A second fuse 400b connects bus 414 to a second device that is redundant to the first device. During testing, the second device was determined to be properly operating. Thus, as shown in FIG. 4B, laser light 412 is being used to burn or cut fuse 400a, thereby removing the bad device from bus 414.

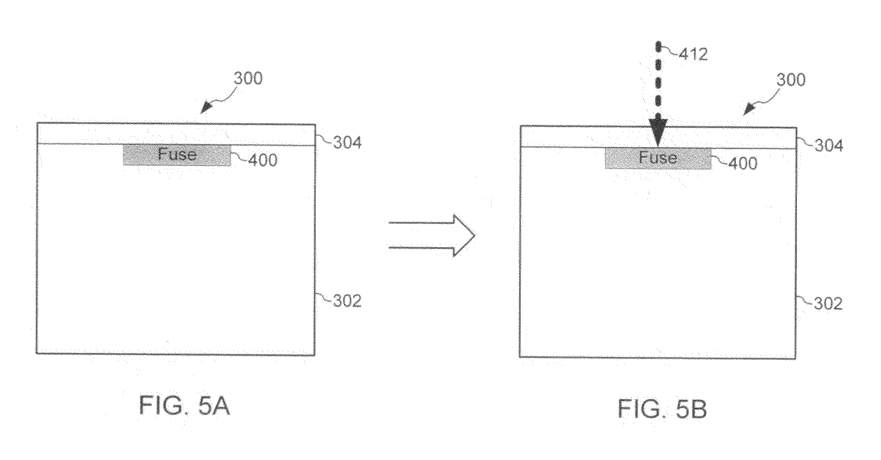

FIGS. 5A-B are diagrams illustrating a method for manufacturing and laser programming an integrated circuit according to an embodiment of the present invention. As will be understood by persons skilled in the relevant art(s), this method does not require after-fuse photolithography and etching steps as are required with conventional manufacturing and laser programming techniques.

FIG. 5A is a diagram that illustrates the formation of a thin passivation layer 304 over a metal layer 302 that includes a fuse 400. The passivation layer 304 is less than 4,500 angstroms thick in order to enable laser programming of fuses such as fuse 400. In embodiments, passivation layer 304 has a thickness that is in a range of about 2,000 angstroms to about 4,000 angstroms in order to enable laser programming.

FIG. 5B is a diagram illustrating the use of laser light 412 to blow or cut fuse 400. As can be seen in FIG. 5B, there is no need for an etched window for laser pass-through.

various embodiments of the present invention have been described above, it should be understood that they have been presented by way of example, and not limitation. It will be apparent to persons skilled in the relevant art(s) that various changes can be made therein without departing from the scope of the invention. Furthermore, it should be appreciated that the detailed description of the present invention provided herein, and not the summary and abstract sections, is intended to be used to interpret the claims. The summary and abstract sections may set forth one or more but not all exemplary embodiments of the present invention as contemplated by the inventors.

1. An integrated circuit, comprising:
a metal layer that includes at least one fuse; and
a passivation layer deposited over the metal layer,
wherein the passivation layer is less than 4,500 angstroms thick to enable laser programming of the at least one fuse without having to etch the passivation layer in the area of the at least one fuse prior to laser programming.

2. The integrated circuit of claim 1, wherein the passivation layer is less than 4,000 angstroms thick.

3. The integrated circuit of claim 1, wherein the passivation layer is less than 3,000 angstroms thick.

4. The integrated circuit of claim 1, wherein the passivation layer is less than 2,500 angstroms thick.

5. The integrated circuit of claim 1, wherein the metal layer includes copper metal conductors.

6. The integrated circuit of claim 5, wherein the copper metal conductors are protected by a barrier metal.

7. The integrated circuit of claim 6, wherein the barrier metal is one of titanium nitride and silicon nitride.

8. A method of manufacturing an integrated circuit; comprising:
(1) forming at least one fuse in a metal layer of an integrated circuit;
(2) depositing a passivation layer that is less than 4,500 angstroms thick over the metal layer; and
(3) laser programming the at least one fuse.

9. The method of claim 8, wherein step (2) comprises depositing a passivation layer that is less than 4,000 angstroms thick over the metal layer.

10. The method of claim 8, wherein step (2) comprises depositing a passivation layer that is less than 3,000 angstroms thick over the metal layer.

11. The method of claim 8, wherein step (2) comprises depositing a passivation layer that is less than 2,500 angstroms thick over the metal layer.

12. The method of claim 8, further comprising:
(4) forming at least one copper metal conductor in the metal layer.

13. The method of claim 12, further comprising:
(5) protecting the at least one copper metal conductor with a barrier metal.

14. The method of claim 12, further comprising:
(5) protecting the at least one copper metal conductor with titanium nitride or silicon nitride.

15. A method of forming an integrated circuit; comprising:
(1) selecting an integrated circuit that includes a plurality of fuses in a metal layer of the integrated circuit, wherein the integrated circuit includes a passivation layer that is less than 4,500 angstroms thick over the metal layer; and
(2) laser programming the plurality of fuses.

16. The method of claim 15, wherein step (1) comprises selecting an integrated circuit wherein the integrated circuit includes a passivation layer that is less than 4,000 angstroms thick over the metal layer.

17. The method of claim 15, wherein step (1) comprises selecting an integrated circuit wherein the integrated circuit includes a passivation layer that is less than 3,000 angstroms thick over the metal layer.

18. The method of claim 15, wherein step (1) comprises selecting an integrated circuit wherein the integrated circuit includes a passivation layer that is less than 2,500 angstroms thick over the metal layer.

19. The method of claim 15, wherein step (1) comprises selecting an integrated circuit that includes a plurality of copper metal conductors in the metal layer.

20. The method of claim 19, wherein step (1) comprises selecting an integrated circuit wherein the copper metal conductors are protected by a barrier metal.
